(19) United States
(12) Patent Application Publication
(10) Pub. No.: US 2026/0271739 A1
(43) Pub. Date: Sep. 10, 2026

(54) STRUCTURES FOR COPPER MIGRATION MITIGATION IN WAFER-LEVEL CHIP SCALE PACKAGES

(71) Applicant: STMicroelectronics International N.V., Geneva (CH)

(72) Inventors: Yong CHEN, Singapore (SG); David GANI, Singapore (SG)

(73) Assignee: STMicroelectronics International N.V., Geneva (CH)

(21) Appl. No.: 19/538,040

(22) Filed: Feb. 12, 2026

Related U.S. Application Data
(60) Provisional application No. 63/767,142, filed on Mar. 5, 2025.

(51) Int. Cl. H10W 70/08; H10W 70/00; H10P 58/00

(52) U.S. Cl. CPC H10W 70/08; H10W 70/099; H10P 58/00

(57) ABSTRACT

A process flow for forming a Wafer-Level Chip Scale Package (WLCSP) provides protection against copper-ion migration while enabling high-density redistribution layers. The process includes forming first and second passivation layers with redistribution layer (RDL) conductors between them. Embodiments herein utilize different barrier structures between adjacent RDL conductors to inhibit copper-ion migration. In a first embodiment, a groove structure in the first passivation layer creates an extended pathway between RDL conductors. A second embodiment utilizes an opening in the first passivation layer to achieve similar protection. A third embodiment utilizes a through-hole structure penetrating multiple passivation layers, which serves as a migration barrier and accommodates additional RDL routing. These barrier structures increase the effective path length that copper-ions travel between adjacent RDL conductors, thereby reducing the likelihood of electrical shorts while maintaining high I/O density capabilities. This process is performed at wafer-level before singulation into individual packages.

### RELATED APPLCATION

This Application claims priority to United States Provisional Application for Patent No. 63/767,142, filed Mar. 5, 2025, the contents of which are incorporated by reference in their entirety.

### TECHNICAL FIELD

This disclosure relates to semiconductor packaging, and more particularly to wafer-level chip scale packages (WLCSPs) with features for inhibiting copper ion migration between redistribution layer conductors.

### BACKGROUND

Wafer-Level Chip Scale Packages (WLCSPs) represent a significant advancement in semiconductor packaging technology. Unlike traditional packaging methods where individual integrated circuits (ICs) are first diced from a wafer and then encapsulated, wafer-level chip scale packaging (WLCSP) methods include performance of the packaging steps at the wafer level, prior to singulation. This helps achieve a small form factor, essentially the size of the die itself with minimal packaging overhead, making WLCSPs desirable for use in mobile devices or other space-constrained applications. Furthermore, the resulting shorter interconnections between the die and the package in WLCSPs may result in reduced parasitics, leading to improved signal integrity and higher operating speeds. Also, performing packaging at the wafer level may lower the production cost per package produced.

A typical WLCSP layer build-up begins with a silicon wafer containing integrated circuits. The top surface of this die has bond pads which serve as input/output (I/O) terminals for the IC. A first passivation layer is deposited over the entire wafer, with the first passivation layer including openings at the bond pads. This first passivation layer protects the underlying circuitry from environmental contamination and provides for electrical isolation. A copper redistribution layer (RDL) is then patterned on top of the first passivation layer and serves to connect to the bond pads and reroute signals therefrom to different connection points, allowing for a flexible and space-saving layout of the final package connections. A second passivation layer is deposited over the RDL. Openings are created in the second passivation layer to expose the new connection points, where solder bumps or balls will be placed. These solder bumps or solder balls are the final external connection points of the WLCSP. Ultimately, the packaged and singulated WLCSP chip will be mounted onto a printed circuit board (PCB). The solder bumps or balls are then formed on top of the exposed connection pads of the RDL to thereby provide electrical and mechanical connection to the PCB. The interface between the first and second passivation layers, particularly in the tight spaces between adjacent RDL traces, is a critical area for package reliability and is therefore of particular concern.

A primary reliability concern is copper (Cu) ion migration. In WLCSPs, as the spacing between RDL lines decreases to achieve higher connection density, the risk of this migration increases. The interface between the first and second passivation layers provides a preferential pathway for this migration. This interface is often less dense and may contain defects, such as microscopic voids or impurities, compared to the bulk passivation material itself, making it easier for copper ions to move. The migrating copper ions can accumulate and form conductive elements that bridge the gap between adjacent RDL lines. This creates an unintended, low- resistance electrical path, leading to increased leakage current. This leakage current degrades device performance and may resultingly lead to short circuits or device failure. This is undesirable.

Several approaches have been attempted to mitigate this copper ion migration issue. One approach is to increase the spacing between RDL lines, which reduces the electric field strength and thus lowers a driving force for electromigration. Another approach involves improving the adhesion between the stacked passivation layers by optimizing process parameters during their deposition. However, these known approaches have limitations. Increasing RDL spacing directly conflicts with the desire for higher I/O density and smaller package size, and improving passivation adhesion through process optimization is also limited as there is a practical limit to how much adhesion can be improved.

As such, further development is still needed in order to mitigate or eliminate the concern of copper ion migration.

### SUMMARY

A method of forming a wafer-level chip scale package (WLCSP) includes forming a first passivation layer over a semiconductor substrate having a conductive pad exposed at a surface thereof. The method includes forming a first opening in the first passivation layer. The method includes forming first and second redistribution layer (RDL) conductors over the first passivation layer, wherein the first RDL conductor is electrically connected to the conductive pad. The method includes forming a second passivation layer over the first and second RDL conductors. The method includes forming a second opening through at least one of the first and second passivation layers between the first and second RDL conductors, wherein the second opening creates an elongated path between the first and second RDL conductors to inhibit copper ion migration therebetween. The method includes forming a solder ball on an expand contact region of the first RDL conductor.

The method may include forming the second opening by forming a groove structure in the first passivation layer between the first and second RDL conductors.

The method may include forming the first opening by forming recessed regions in the first passivation layer, and wherein the first and second RDL conductors are formed within the recessed regions.

The method may include forming the second opening by forming an opening through both the first and second passivation layers between the first and second RDL conductors.

The method may further include forming a third passivation layer over the second passivation layer, and forming a third RDL conductor within the second opening and extending through the third passivation layer.

The method may include forming the first RDL conductor by forming an expanded contact region having a T-shaped profile.

The method may further include depositing a conductive seed layer on the first passivation layer before forming the first and second redistribution layer (RDL) conductors.

The method may include forming the first RDL conductor by forming an expanded contact region having a T-shaped profile by electroplating copper so that an upper portion of the contact region is wider than an opening in the second passivation layer.

The method may further include forming a third passivation layer over the second passivation layer, forming an opening that extends through at least the first, second, and third passivation layers, and forming a third redistribution layer conductor within the opening.

The method may further include performing a singulation step to separate individual WLCSPs from the semiconductor wafer after the solder ball has been formed on the expanded contact region of the first RDL conductor.

A wafer-level chip scale package (WLCSP) includes a semiconductor substrate having a conductive pad exposed at a surface thereof. The WLCSP includes a first passivation layer disposed over the semiconductor substrate. The WLCSP includes first and second redistribution layer (RDL) conductors disposed over the first passivation layer, wherein the first RDL conductor is electrically connected to the conductive pad. The WLCSP includes a second passivation layer disposed over the first and second RDL conductors. The WLCSP includes an opening defined through at least one of the first and second passivation layers between the first and second RDL conductors, wherein the opening creates an elongated path between the first and second RDL conductors to inhibit copper ion migration therebetween. The WLCSP includes a solder ball on an expanded contact region of the first RDL conductor.

The WLCSP may include the opening defining a groove structure extending into the first passivation layer between the first and second RDL conductors.

The WLCSP may further include recessed regions defined in the first passivation layer, wherein the first and second RDL conductors are formed within the recessed regions.

The WLCSP may include the opening extending through both the first and second passivation layers between the first and second RDL conductors.

The WLCSP may further include a third passivation disposed layer over the second passivation layer, and a third RDL conductor within the opening and extending through the third passivation layer.

The WLCSP may include the first RDL conductor having an expanded contact region with a T-shaped profile.

The WLCSP may further include a third passivation layer disposed over the second passivation layer, and a third redistribution layer conductor formed through an opening that extends through the first, second, and third passivation layers.

The WLCSP may include the first RDL conductor having an expanded contact region with a T-shaped profile formed by electroplating copper onto a portion of the RDL conductor that extends through the second passivation layer.

### BRIEF DESCRIPTION OF THE DRAWINGS

FIG. 1A is a diagrammatical cross-sectional view of a semiconductor substrate with an exposed conductive pad, according to a first embodiment.

FIG. 1B is a diagrammatical cross-sectional view showing the formation of a first passivation layer over the substrate and pad of FIG. 1A.

FIG. 1C is a diagrammatical cross-sectional view showing the formation of recessed regions and a groove structure within the first passivation layer of FIG. 1B.

FIG. 1D is a diagrammatical cross-sectional view showing the formation of redistribution layer conductors within the recessed regions of FIG. 1C.

FIG. 1E is a diagrammatical cross-sectional view showing the formation of a second passivation layer over the redistribution layer conductors and groove structure of FIG. 1D.

FIG. 1F is a diagrammatical cross-sectional view showing the formation of an opening through the second passivation layer of FIG. 1E.

FIG. 1G is a diagrammatical cross-sectional view showing the formation of an expanded contact region of the redistribution layer conductor of FIG. 1F.

FIG. 1H is a diagrammatical cross-sectional view showing the formation of a solder ball on the expanded contact region of FIG. 1G.

FIG. 2A is a diagrammatical cross-sectional view of a semiconductor substrate with an exposed conductive pad, according to a second embodiment.

FIG. 2B is a diagrammatical cross-sectional view showing the formation of a first passivation layer over the substrate and pad of FIG. 2A.

FIG. 2C is a diagrammatical cross-sectional view showing the formation of an opening and recess within the first passivation layer of FIG. 2B.

FIG. 2D is a diagrammatical cross-sectional view showing the formation of redistribution layer conductors within the patterned regions of FIG. 2C.

FIG. 2E is a diagrammatical cross-sectional view showing the formation of a second passivation layer over the redistribution layer conductors of FIG. 2D.

FIG. 2F is a diagrammatical cross-sectional view showing the formation of an opening through the second passivation layer of FIG. 2E.

FIG. 2G is a diagrammatical cross-sectional view showing the formation of an expanded contact region of the redistribution layer conductor of FIG. 2F.

FIG. 2H is a diagrammatical cross-sectional view showing the formation of a solder ball on the expanded contact region of FIG. 2G.

FIG. 3A is a diagrammatical cross-sectional view of a semiconductor substrate with an exposed conductive pad, according to a third embodiment.

FIG. 3B is a diagrammatical cross-sectional view showing the formation of a first passivation layer over the substrate and pad of FIG. 3A.

FIG. 3C is a diagrammatical cross-sectional view showing the formation of a recess within the first passivation layer of FIG. 3B.

FIG. 3D is a diagrammatical cross-sectional view showing the formation of redistribution layer conductors in FIG. 3C.

FIG. 3E is a diagrammatical cross-sectional view showing the formation of a second passivation layer over the redistribution layer conductors of FIG. 3D.

FIG. 3F is a diagrammatical cross-sectional view showing the formation of an opening through the second passivation layer of FIG. 3E.

FIG. 3G is a diagrammatical cross-sectional view showing the formation of expanded contact regions of the redistribution layer conductors of FIG. 3F.

FIG. 3H is a diagrammatical cross-sectional view showing the formation of an opening through both passivation layers of FIG. 3G.

FIG. 3I is a diagrammatical cross-sectional view showing the formation of a third passivation layer and an opening therein over the structure of FIG. 3H.

FIG. 3J is a diagrammatical cross-sectional view showing the formation of an additional redistribution layer conductor within the opening of FIG. 3I.

FIG. 3K is a diagrammatical cross-sectional view showing the formation of a solder ball on the expanded contact region of FIG. 3J.

### DETAILED DESCRIPTION

The following disclosure enables a person skilled in the art to make and use the subject matter described herein. The general principles outlined in this disclosure can be applied to embodiments and applications other than those detailed above without departing from the spirit and scope of this disclosure. It is not intended to limit this disclosure to the embodiments shown, but to accord it the widest scope consistent with the principles and features disclosed or suggested herein.

Now described is a process flow for forming a Wafer-Level Chip Scale Package (WLCSP) that provides for robust protection against copper ion migration. This process flow facilitates enables the formation of high-density redistribution layers while maintaining package reliability through a groove structure design that will be described hereinbelow.

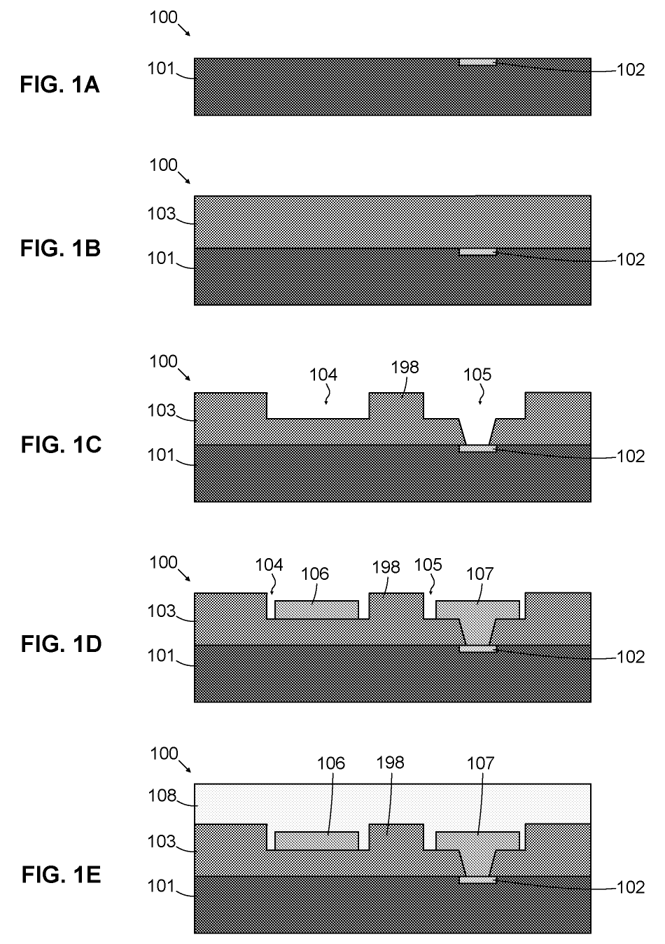

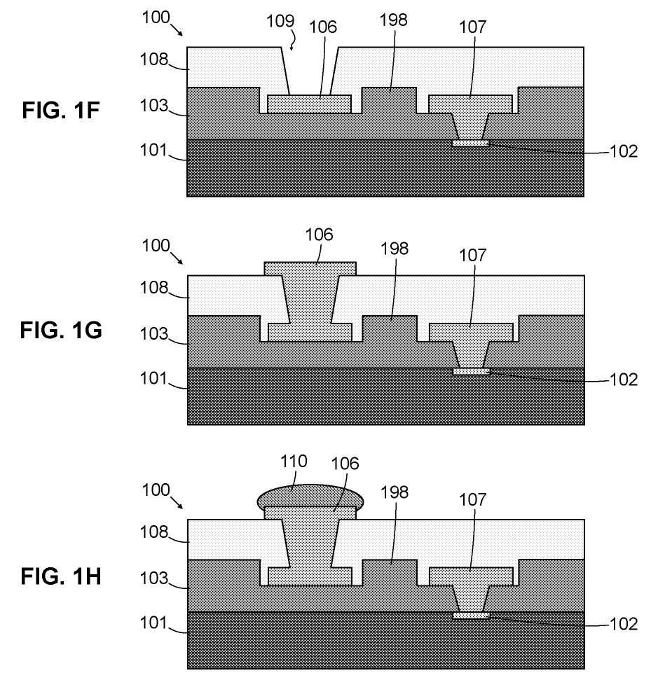

Referring first to FIG. 1A, shown is a portion of a semiconductor wafer that includes a semiconductor substrate region 101 covered by an interconnect region. The semiconductor substrate region has integrated circuits formed therein and thereon. The interconnect region includes multiple metallization levels and contact structures for connecting the integrated circuits. At the uppermost level of the interconnect region is at least one conductive pad 102. The conductive pad 102 typically comprises copper, aluminum, or other suitable conductive materials and serves as an input/output connection point for the underlying integrated circuitry.

As shown in FIG. 1B, the process flow continues with a first passivation layer 103 being formed over the substrate 101 and pad 102. The first passivation layer 103 may comprise silicon dioxide, silicon nitride, polyimide, or other suitable dielectric materials. This first passivation layer 103 is deposited using a technique such as chemical vapor deposition (CVD), plasma- enhanced chemical vapor deposition (PECVD), spin coating, or other suitable deposition technique.

Proceeding next in the process flow as shown in FIG. 1C, a recessed regions 104, 105 are formed within the first passivation layer 103. These recessed regions are formed through photolithography and etching processes. More particularly, a photoresist layer may be deposited and patterned to define the locations of the recessed regions 104, 105, and then an etching may be performed to remove portions of the first passivation layer 103. This etching also serves to form a groove structure 198 within the first passivation layer 103 between the recessed regions 104, 105. The groove structure 198 is serves to create an extended pathway between areas where adjacent redistribution layer (RDL) conductors will subsequently be formed.

Next, as shown in FIG. 1D, redistribution layer conductors 106, 107 are formed within the recessed regions 104, 105 via deposition of a seed layer followed by photolithographic patterning and electroplating of copper. The RDL conductors 106, 107 serve to redistribute electrical connections from the pad 102 to desired external connection locations. The groove structure 198 remains as a physical barrier between adjacent RDL conductors 106, 107.

The process flow continues in FIG. 1E, which shows the formation of a second passivation layer 108 over the RDL conductors 106, 107 and the groove structure 198. This second passivation layer 108 provides environmental protection and electrical isolation for the RDL conductors 106, 107. The second passivation layer 108 may be comprised of similar materials as the first passivation layer 103. As explained, the groove structure 198 creates an elongated path between adjacent RDL conductors 106, 107. This increased path length serves to inhibit copper ion migration between the RDL conductors 106, 107 by forcing migrating ions to travel a greater effective distance compared to the direct spacing between the conductors. The actual path length that copper ions must travel along the interface between passivation layers 103, 108 is significantly increased by the presence of the groove structure 198, thereby reducing the likelihood of copper ion migration and subsequent electrical shorts between the RDL conductors 106, 107, without requiring increased spacing between RDL conductors, thereby maintaining the ability to achieve high I/O density in the final package.

Next, as shown in FIG. 1F, an opening 109 is formed through the second passivation layer 108 using photolithography and etching to expose portions of the RDL conductors 106, 107 for subsequent electrical connection. As illustrated in FIG. 1G, the RDL conductor 106 is then built up within and above the opening 109 to form an expanded contact region having a T-shaped profile, with the upper portion being wider than the opening 109 itself. This expanded contact region provides increased surface area for subsequent electrical connections while maintaining a smaller passivation layer opening.

A solder ball 110 is then formed on or attached to the expanded contact region of the RDL conductor 106, as shown in FIG. 1H. This solder ball provides the external electrical connection point for the completed WLCSP.

The process steps described above are performed simultaneously across an entire semiconductor wafer containing multiple semiconductor substrates 101, as is typical in wafer-level chip scale packaging. While the figures illustrate a single pad 102 and two redistribution layer conductors 106, 107, it should be understood that each semiconductor substrate 101 may contain any number of pads 102 and associated RDL conductors arranged in various patterns and configurations as needed for the particular integrated circuit design. Similarly, while a particular shape and arrangement of the groove structure 198 is shown between adjacent RDL conductors, the groove structure may take various suitable forms and dimensions while maintaining its function of extending the migration path between RDL conductors.

Upon completion of these steps, the wafer contains numerous completed WLCSPs. A singulation operation is then performed to separate the wafer into individual packages, each including the semiconductor substrate with active devices, the interconnect region with its metallization levels and contact structures, the redistribution layer conductors for signal routing, and the first and second passivation layers 103, 108, with the groove structures 198 between adjacent RDL conductors to inhibit copper ion migration. Each packaged die maintains a small form factor essentially the same size as its portion of the semiconductor substrate. Following singulation, the individual WLCSPs are ready for mounting onto printed circuit boards through conventional surface mount processes using the solder balls 110 as connection points.

Now described is another embodiment of a process flow for forming a Wafer-Level Chip Scale Package (WLCSP) that provides for robust protection against copper ion migration.

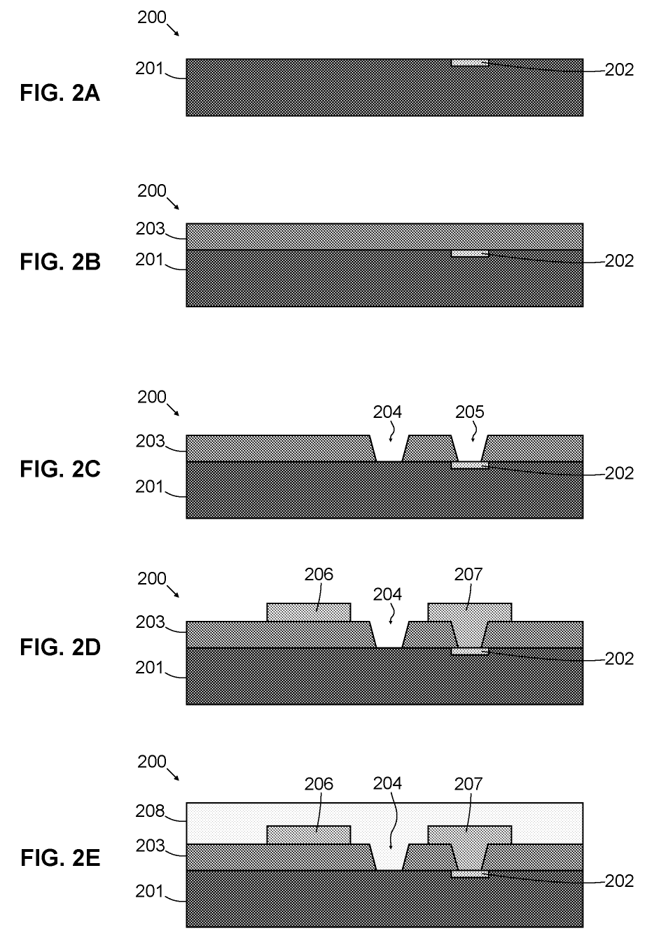

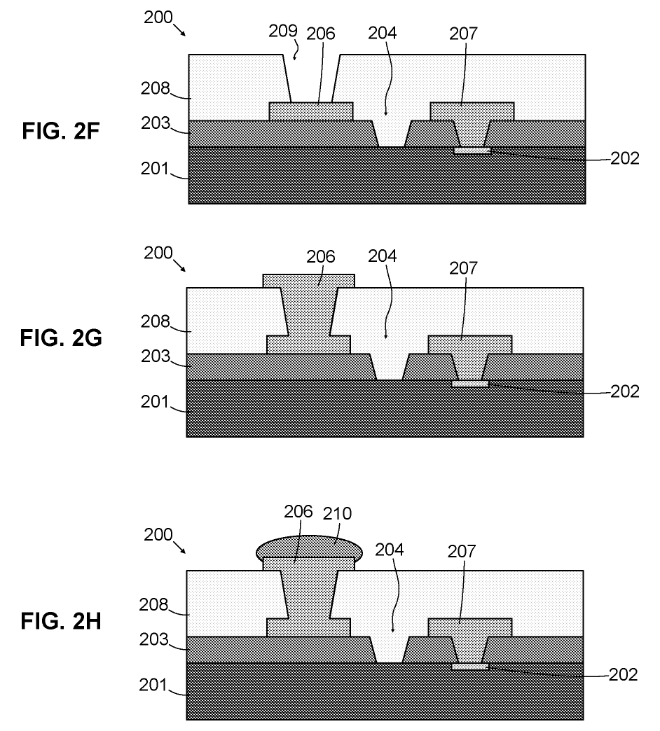

Referring first to FIG. 2A, shown is a portion of a semiconductor wafer that includes a semiconductor substrate region 201 covered by an interconnect region. The semiconductor substrate region has integrated circuits formed therein and thereon. The interconnect region includes multiple metallization levels and contact structures for connecting the integrated circuits. At the uppermost level of the interconnect region is at least one conductive pad 202. The conductive pad 202 typically comprises copper, aluminum, or other suitable conductive materials and serves as an input/output connection point for the underlying integrated circuitry.

As shown in FIG. 2B, the process flow continues with a first passivation layer 203 being formed over the substrate 201 and pad 202. The first passivation layer 203 may comprise silicon dioxide, silicon nitride, polyimide, or other suitable dielectric materials. This first passivation layer 203 is deposited using a technique such as chemical vapor deposition (CVD), plasma-enhanced chemical vapor deposition (PECVD), spin coating, or other suitable deposition technique.

Proceeding next in the process flow as shown in FIG. 2C, an opening 204 and recess 205 are formed within the first passivation layer 203. These features are formed through photolithography and etching processes. More particularly, a photoresist layer may be deposited and patterned to define the locations of the opening 204 and recess 205, and then an etching may be performed to remove portions of the first passivation layer 203. The opening 204 serves to create an extended pathway between areas where adjacent redistribution layer (RDL) conductors will subsequently be formed.

Next, as shown in FIG. 2D, redistribution layer conductors 206, 207 are formed within the patterned regions via deposition of a seed layer followed by photolithographic patterning and electroplating of copper. The RDL conductors 206, 207 serve to redistribute electrical connections from the pad 202 to desired external connection locations. The opening 204 remains as a physical barrier between adjacent RDL conductors 206, 207.

The process flow continues in FIG. 2E, which shows the formation of a second passivation layer 208 over the RDL conductors 206, 207. This second passivation layer 208 provides environmental protection and electrical isolation for the RDL conductors 206, 207. The second passivation layer 208 may be comprised of similar materials as the first passivation layer 203. As explained, the opening 204 creates an elongated path between adjacent RDL conductors 206, 207. This increased path length serves to inhibit copper ion migration between the RDL conductors 206, 207 by forcing migrating ions to travel a greater effective distance compared to the direct spacing between the conductors.

Next, as shown in FIG. 2F, an opening 209 is formed through the second passivation layer 208 using photolithography and etching to expose portions of the RDL conductor 206 for subsequent electrical connection. As illustrated in FIG. 2G, the RDL conductor 206 is then built up within and above the opening 209 to form an expanded contact region having a T-shaped profile, with the upper portion being wider than the opening 209 itself. This expanded contact region provides increased surface area for subsequent electrical connections while maintaining a smaller passivation layer opening.

A solder ball 210 is then formed on or attached to the expanded contact region of the RDL conductor 206, as shown in FIG. 2H. This solder ball provides the external electrical connection point for the completed WLCSP.

As with the previous embodiment, these process steps are performed simultaneously across an entire semiconductor wafer containing multiple semiconductor substrates 201. While the figures illustrate a single pad 202 and two redistribution layer conductors 206, 207, it should be understood that each semiconductor substrate 201 may contain any number of pads 202 and associated RDL conductors arranged in various patterns and configurations as needed for the particular integrated circuit design. Similarly, while a particular shape and arrangement of the opening 204 is shown between adjacent RDL conductors, the opening may take various suitable forms and dimensions while maintaining its function of extending the migration path between RDL conductors.

Upon completion of these steps, the wafer contains numerous completed WLCSPs. A singulation operation is then performed to separate the wafer into individual packages, each including the semiconductor substrate with active devices, the interconnect region with its metallization levels and contact structures, the redistribution layer conductors for signal routing, and the first and second passivation layers 203, 208. Each packaged die maintains a small form factor essentially the same size as its portion of the semiconductor substrate. Following singulation, the individual WLCSPs are ready for mounting onto printed circuit boards through conventional surface mount processes using the solder balls 210 as connection points.

A third embodiment of a process flow for forming a Wafer-Level Chip Scale Package (WLCSP) will now be described.

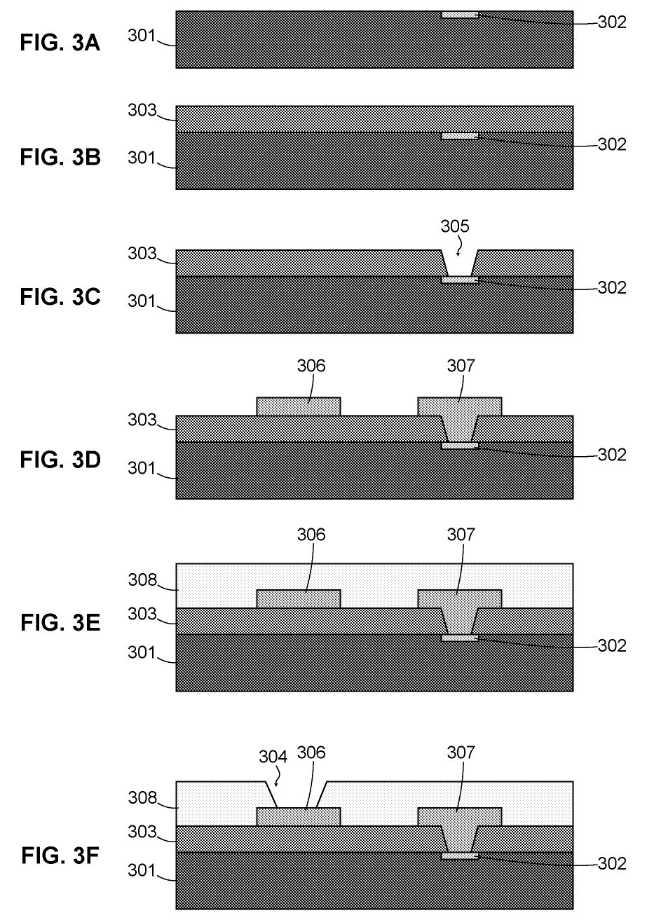

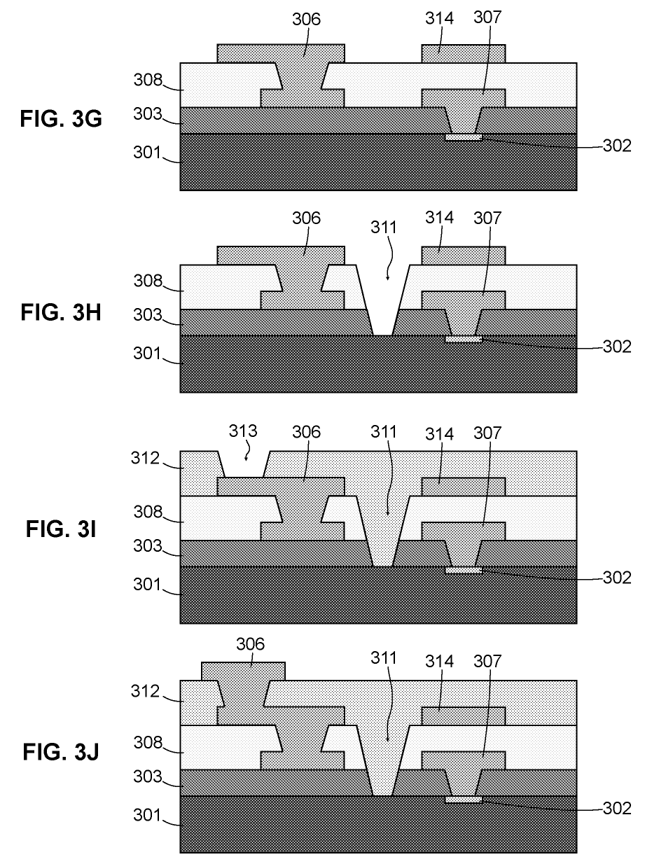

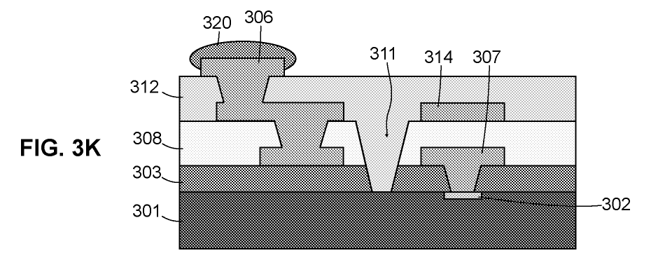

Referring first to FIG. 3A, shown is a portion of a semiconductor wafer that includes a semiconductor substrate region 301 covered by an interconnect region. The semiconductor substrate region has integrated circuits formed therein and thereon. The interconnect region includes multiple metallization levels and contact structures for connecting the integrated circuits. At the uppermost level of the interconnect region is at least one conductive pad 302. The conductive pad 302 typically comprises copper, aluminum, or other suitable conductive materials and serves as an input/output connection point for the underlying integrated circuitry.

As shown in FIG. 3B, the process flow continues with a first passivation layer 303 being formed over the substrate 301 and pad 302. The first passivation layer 303 may comprise silicon dioxide, silicon nitride, polyimide, or other suitable dielectric materials. This first passivation layer 303 is deposited using a technique such as chemical vapor deposition (CVD), plasma-enhanced chemical vapor deposition (PECVD), spin coating, or other suitable deposition technique.

Proceeding next in the process flow as shown in FIG. 3C, a recess 305 is formed within the first passivation layer 303 through photolithography and etching processes.

Next, as shown in FIG. 3D, redistribution layer conductors 306, 307 are formed via deposition of a seed layer followed by photolithographic patterning and electroplating of copper. The RDL conductors 306, 307 serve to redistribute electrical connections from the pad 302 to desired external connection locations.

The process flow continues in FIG. 3E with the formation of a second passivation layer 308 over the RDL conductors 306, 307. This second passivation layer 308 provides environmental protection and electrical isolation for the RDL conductors 306, 307.

As shown in FIG. 3F, an opening 304 is formed through the second passivation layer 308 to expose portions of RDL conductor 306. Moving to FIG. 3G, the RDL conductors 306, 307 are built up within and above their respective openings to form expanded contact regions having T-shaped profiles.

In FIG. 3H, an opening 311 is formed through both the second passivation layer 308 and the first passivation layer 303. This opening 311 serves to create an elongated path between adjacent RDL conductors, inhibiting copper ion migration by forcing migrating ions to travel a greater effective distance. This opening 311 is also configured to accommodate an additional redistribution layer conductor that will be subsequently formed.

FIG. 3I shows the formation of a third passivation layer 312, followed by the formation of an opening 313 to expose portions of RDL conductor 306. In FIG. 3J, an additional redistribution layer conductor 314 is formed within opening 311 and extends through the third passivation layer 312, providing an additional layer of routing capability and interconnection options.

Finally, as shown in FIG. 3K, a solder ball 320 is formed on or attached to the expanded contact region of RDL conductor 306. This solder ball provides the external electrical connection point for the completed WLCSP, while the multi-level RDL structure including conductors 306, 307, and 314 provides enhanced routing flexibility.

As with the previous embodiments, these process steps are performed simultaneously across an entire semiconductor wafer containing multiple semiconductor substrates 301. While the figures illustrate specific RDL conductors and openings, it should be understood that each semiconductor substrate 301 may contain any number of pads, RDL conductors, and associated features arranged in various patterns and configurations as needed for the particular integrated circuit design. The opening 311 through both passivation layers provides an effective barrier against copper ion migration while maintaining the ability to achieve high I/O density in the final package.

Upon completion of these steps, the wafer contains numerous completed WLCSPs. A singulation operation is then performed to separate the wafer into individual packages, each including the semiconductor substrate with active devices, the interconnect region with its metallization levels and contact structures, the redistribution layer conductors for signal routing, and the first, second, and third passivation layers 303, 308, 312. Each packaged die maintains a small form factor essentially the same size as its portion of the semiconductor substrate. Following singulation, the individual WLCSPs are ready for mounting onto printed circuit boards through conventional surface mount processes using the solder balls 320 as connection points.

Finally, it is evident that modifications and variations can be made to what has been described and illustrated herein without departing from the scope of this disclosure.

Although this disclosure has been described with a limited number of embodiments, those skilled in the art, having the benefit of this disclosure, can envision other embodiments that do not deviate from the disclosed scope. Furthermore, skilled persons can envision embodiments that represent various combinations of the embodiments disclosed herein made in various ways.

1. A method of forming a wafer-level chip scale package (WLCSP), comprising:
forming a first passivation layer over a semiconductor substrate having a conductive pad exposed at a surface thereof;
forming a first opening in the first passivation layer;
forming first and second redistribution layer (RDL) conductors over the first passivation layer, wherein the first RDL conductor is electrically connected to the conductive pad;
forming a second passivation layer over the first and second RDL conductors;
forming a second opening through at least one of the first and second passivation layers between the first and second RDL conductors, wherein the second opening creates an elongated path between the first and second RDL conductors to inhibit copper ion migration therebetween; and
forming a solder ball on an expand contact region of the first RDL conductor.

2. The method of claim 1, wherein forming the second opening comprises forming a groove structure in the first passivation layer between the first and second RDL conductors.

3. The method of claim 1, wherein forming the first opening comprises forming recessed regions in the first passivation layer, and wherein the first and second RDL conductors are formed within the recessed regions.

4. The method of claim 1, wherein forming the second opening comprises forming an opening through both the first and second passivation layers between the first and second RDL conductors.

5. The method of claim 4, further comprising:
forming a third passivation layer over the second passivation layer; and
forming a third RDL conductor within the second opening and extending through the third passivation layer.

6. The method of claim 1, wherein forming the first RDL conductor comprises forming an expanded contact region having a T-shaped profile.

7. The method of claim 1, further comprising depositing a conductive seed layer on the first passivation layer before forming the first and second redistribution layer (RDL) conductors.

8. The method of claim 1, wherein forming the first RDL conductor comprises forming an expanded contact region having a T-shaped profile by electroplating copper so that an upper portion of the contact region is wider than an opening in the second passivation layer.

9. The method of claim 1, further comprising:
forming a third passivation layer over the second passivation layer;
forming an opening that extends through at least the first, second, and third passivation layers; and
forming a third redistribution layer conductor within the opening.

10. The method of claim 1, further comprising performing a singulation step to separate individual WLCSPs from the semiconductor wafer after the solder ball has been formed on the expanded contact region of the first RDL conductor.

11. The method of claim 1, wherein forming the first and second redistribution layer conductors comprises depositing a conductive seed layer on the first passivation layer and electroplating copper onto the seed layer.

12. A wafer-level chip scale package (WLCSP), comprising:
a semiconductor substrate having a conductive pad exposed at a surface thereof;
a first passivation layer disposed over the semiconductor substrate;
first and second redistribution layer (RDL) conductors disposed over the first passivation layer, wherein the first RDL conductor is electrically connected to the conductive pad;
a second passivation layer disposed over the first and second RDL conductors;
an opening defined through at least one of the first and second passivation layers between the first and second RDL conductors, wherein the opening creates an elongated path between the first and second RDL conductors to inhibit copper ion migration therebetween; and
a solder ball on an expanded contact region of the first RDL conductor.

13. The WLCSP of claim 12, wherein the opening defines a groove structure extending into the first passivation layer between the first and second RDL conductors.

14. The WLCSP of claim 12, further comprising recessed regions defined in the first passivation layer, wherein the first and second RDL conductors are formed within the recessed regions.

15. The WLCSP of claim 12, wherein the opening extends through both the first and second passivation layers between the first and second RDL conductors.

16. The WLCSP of claim 15, further comprising:
a third passivation disposed layer over the second passivation layer; and
a third RDL conductor within the opening and extending through the third passivation layer.

17. The WLCSP of claim 12, wherein the first RDL conductor comprises an expanded contact region having a T-shaped profile.

18. The WLCSP of claim 12, further comprising a third passivation layer disposed over the second passivation layer, and a third redistribution layer conductor formed through an opening that extends through the first, second, and third passivation layers.

19. The WLCSP of claim 12, wherein the first RDL conductor comprises an expanded contact region having a T-shaped profile formed by electroplating copper onto a portion of the RDL conductor that extends through the second passivation layer.

20. The WLCSP of claim 12, wherein the opening between the first and second RDL conductors is formed by photolithography and etching of at least one of the first passivation layer and the second passivation layer.
